(19) United States
(12) Patent Application Publication
(10) Pub. No.: US 2023/0309320 A1
(43) Pub. Date: Sep. 28, 2023

(54) EMBEDDED MAGNETORESISTIVE RANDOM ACCESS MEMORY

(71) Applicant: INTERNATIONAL BUSINESS MACHINES CORPORATION, ARMONK, NY (US)

(72) Inventors: Heng Wu, Santa Clara, CA (US); Ruilong Xie, Niskayuna, NY (US); Julien Frougier, Albany, NY (US); Min Gyu Sung, Latham, NY (US); Chen Zhang, Guilderland, NY (US)

(21) Appl. No.: 17/656,045

(22) Filed: Mar. 23, 2022

(51) Int. Cl. H01L 27/22; G11C 11/16; H01L 43/08; H01L 43/14; H01L 43/04

(52) U.S. Cl. CPC H01L 27/228; G11C 11/161; G11C 11/1697; H01L 43/08; H01L 43/14; H01L 43/04

(57) ABSTRACT

Embodiments are disclosed for a system. The system includes a semiconductor structure. The semiconductor structure includes a wafer, multiple transistors, and a magnetoresistive random access memory (MRAM) cell disposed on the backside of the wafer. The transistors are disposed on a front end of line (FEOL) of the wafer. The MRAM cell is connected to a source-drain of the transistors by a contact disposed on the backside of the wafer. The transistors are in direct electrical contact with the MRAM cell by at least one contact.

### BACKGROUND

The present disclosure relates to random access memory (RAM), and more specifically, to embedded magnetoresistive RAM.

Magnetoresistive RAM (MRAM) is a type of solid state, non-volatile memory that uses tunneling magnetoresistance to store information, and can be incorporated into embedded non-volatile memory (ENVM) devices. Such ENVM devices may also be referred to as embedded MRAM (EMRAM), which can include spin transfer torque MRAM (STT-MRAM) or spin-orbit torque MRAM (SOT-MRAM). However, wafers with EMRAM may fabricate the EMRAM in the back end of line (BEOL) of the actual semiconductor wafer. The BEOL can refer to the integration done after transistor formation in the front end of line (FEOL).

Further, due to the complexity of routing in the BEOL, the STT-MRAM can be placed at far backend, which can create high resistance. Backside EMRAM means that embedded memory has a transistor on the other side. Commercial memory devices typically have the transistor and memory on the same side. Such high resistance can result in area loss. Further, for SOT-MRAM, which may be configured with a three-terminal design, the area loss can be even larger. Additionally, placing the STT-MRAM at far backend can increase the cost of producing such devices due to the resultant integration complexity.

### SUMMARY

Embodiments are disclosed for a system. The system includes a semiconductor structure. The semiconductor structure includes a wafer, multiple transistors, and a magnetoresistive random access memory (MRAM) cell disposed on the backside of the wafer. The transistors are disposed on a front end of line (FEOL) of the wafer. The MRAM cell is connected to a source-drain of the transistors by a contact disposed on the backside of the wafer. The transistors are in direct electrical contact with the MRAM cell by at least one contact. Advantageously, such embodiments reduce resistance, and are less costly to fabricate than wafers having MRAM cells on a same side of the wafer as the transistors.

Embodiments are additionally disclosed for a method to fabricate a semiconductor structure. The method includes performing a post wafer flip of a wafer having multiple transistors disposed on a front end of line (FEOL) of the wafer. The method also includes performing backside polishing of the wafer. The method further includes removing sacrificial plugs from a backside of the wafer. The method additionally includes forming contacts in place of the sacrificial plugs. Also, the method includes generating a spin Hall effect (SHE) rail by performing heavy metal SHE rail deposition on the backside of the wafer. Further, the method includes generating a magnetic tunnel junction (MTJ) stack by performing MTJ stack deposition on the SHE rail. Additionally, the method includes performing MTJ patterning on the MTJ stack. The method also includes generating an IBE pillar by performing IBE pillar formation on the patterned MTJ stack. The method further includes performing dielectric encapsulation on the SHE rail and the IBE pillar. The method additionally includes performing self-aligned encapsulation dielectric reactive ion etching (RIE) and SHE rail formation. Also, the method includes performing interlayer dielectric (ILD) fill and chemical-mechanical polishing (CMP) on the IBE pillar and SHE rail. Further, the method includes performing MTJ top contact landing on the IBE pillar. Advantageously, such embodiments reduce resistance, and are less costly to fabricate than wafers having MRAM cells on a same side of the wafer as the transistors.

Further aspects of the present disclosure are directed toward computer program products with functionality similar to the functionality discussed above regarding the computer-implemented method. The present summary is not intended to illustrate each aspect of, every implementation of, and/or every embodiment of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a block diagram of an example embedded magnetoresistive random access memory (EMRAM) fabrication manager, in accordance with some embodiments of the present disclosure.

FIG. 2 is a cross-section view of an example complementary metal-oxide semiconductor (CMOS) device having backside EMRAM, in accordance with some embodiments of the present disclosure.

FIG. 3 is a process flow chart of a method for fabricating a CMOS device having backside EMRAM, in accordance with some embodiments of the present disclosure.

FIGS. 4A, 4B, 4C, 4D, 4E, 4F, 4G, 4H, and 4I are cross-section views of example fabrication states of a wafer, in accordance with some embodiments of the present disclosure.

FIG. 4J is a side perspective view of a wafer having a CMOS device with backside EMRAM, in accordance with some embodiments of the present disclosure.

FIG. 5 is a cross-section view of an example CMOS device having backside EMRAM, in accordance with some embodiments of the present disclosure.

FIG. 6A is a cross-section view of an example CMOS device having backside EMRAM, in accordance with some embodiments of the present disclosure.

FIG. 6B is a side perspective view of a wafer having a CMOS device with backside EMRAM, in accordance with some embodiments of the present disclosure.

FIG. 7 is a cross-section view of an example CMOS device having backside EMRAM, in accordance with some embodiments of the present disclosure.

FIG. 8 is a cross-section view of an example CMOS device having backside EMRAM, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the embodiments described. On the contrary, the intention is to cover all modifications, equivalents, and alternatives falling within the spirit and scope of the present disclosure.

### DETAILED DESCRIPTION

As stated previously, embedded dynamic RAM (EDRAM) can incorporate non-volatile memories, such as, spin transfer torque magnetoresistive RAM (STT-MRAM) or spin-orbit torque MRAM (SOT-MRAM). The STT-MRAM may use spin-aligned (“polarized”) electrons to directly torque the domains of an MRAM cell. Specifically, electrons flowing into a layer that change their spin can develop a torque that transfers to a nearby layer of the memory device, thus performing a write to an MRAM cell. The STT-MRAM may inject current perpendicularly into the magnetic tunnel junction. In contrast, the SOT-MRAM devices can switch the MRAM cell of a free magnetic layer by injecting an in-plane current in an adjacent layer.

As also stated previously, the STT-MRAM can be placed at far backend of the wafer, which can be costly and create high electromagnetic resistance, resulting in area loss. However, for SOT-MRAM, which may be configured with a three-terminal design, the area loss can be even larger than that of the STT-MRAM.

Accordingly, some embodiments of the present disclosure can include a backside EMRAM having a transistor and MRAM cell. Backside EMRAM means that the embedded memory has the transistor on the other side of the CMOS device, in contrast to commercial memory devices, which have the transistor and memory on the same side. Accordingly, some embodiments of the present disclosure can fabricate the wafer by placing the MRAM on the backside of the wafer, and connect the MRAM to a front end of line (FEOL) transistor using a backside contact. Further, in such embodiments the MRAM can be disposed in contact with the backside of transistor without intervening metal layers. In this way, some embodiments of the present disclosure can reduce the resistance penalty typically incurred by current commercial memory devices.

In this way, some embodiments of the present disclosure can provide a memory device that represents an improvement over existing ENVM devices. Specifically, such embodiments may reduce wiring resistance, improve device performance, and reduce the complexity of the routing and wiring in the BEOL.

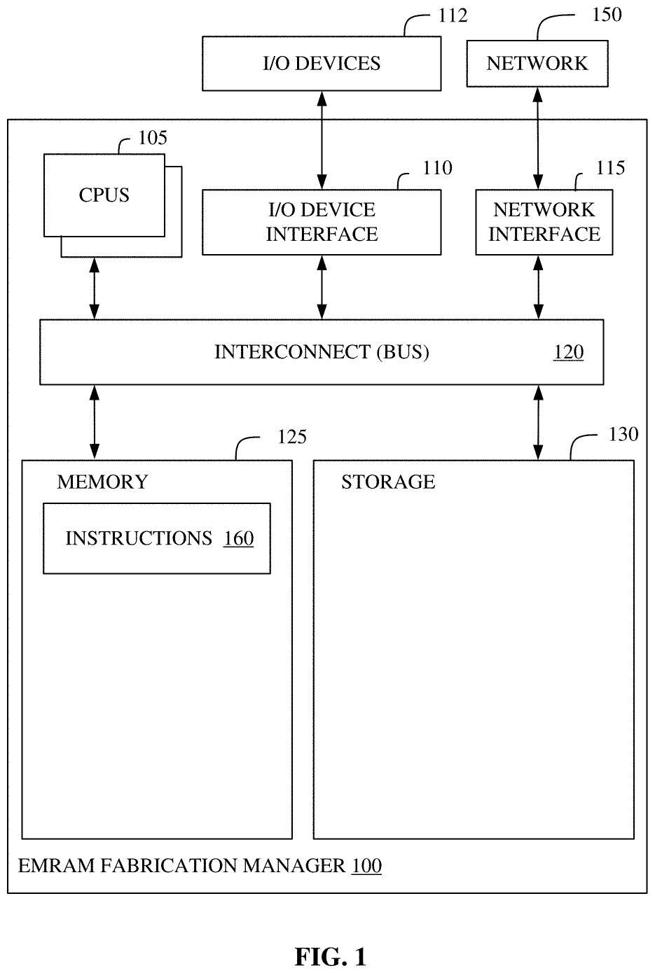

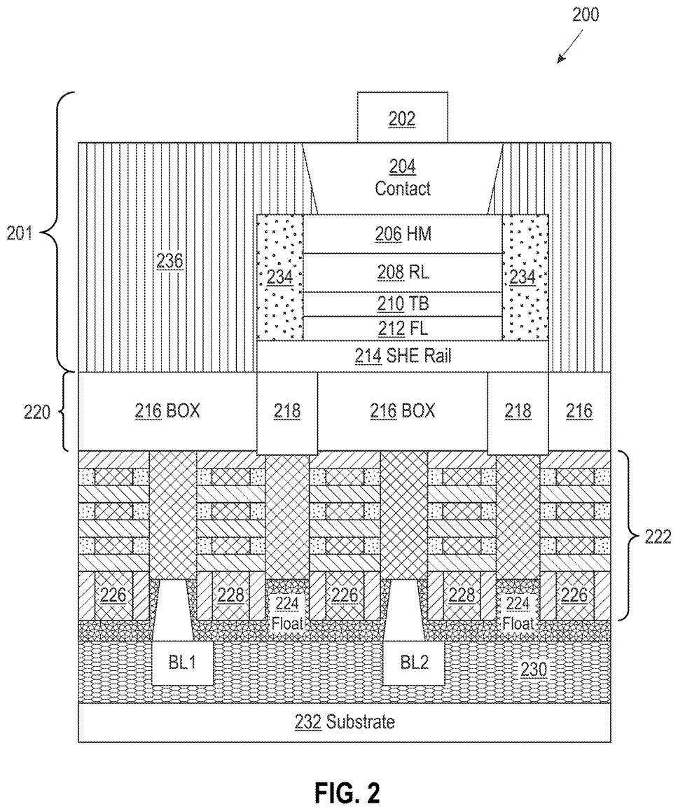

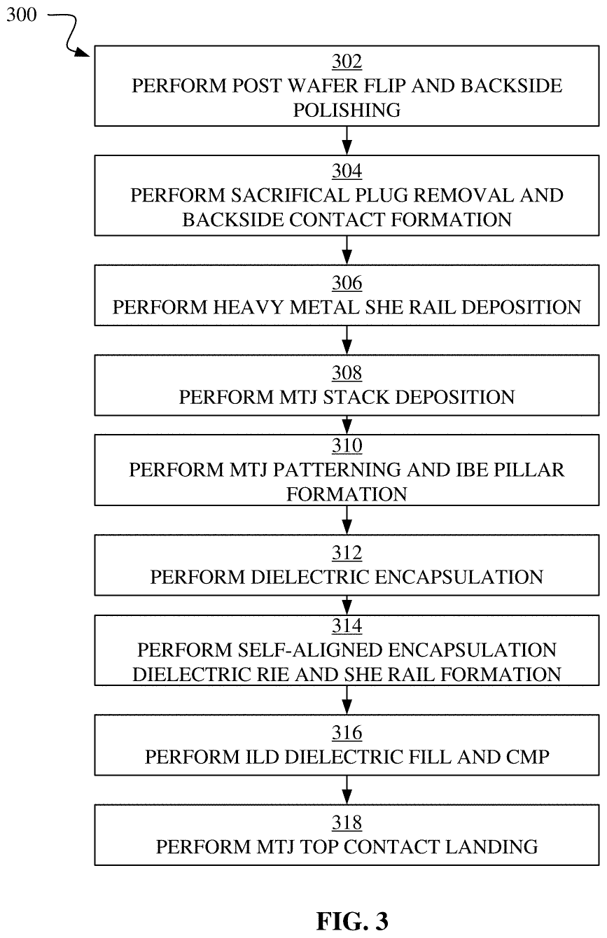

FIG. 1 is a block diagram of an example EDRAM fabrication manager 100, in accordance with some embodiments of the present disclosure. In various embodiments, the example EDRAM fabrication manager 100 can perform the method described in FIG. 3, and/or cause one or more machines to design, fabricate, and/or utilize components as discussed in FIGS. 2, 4A-4J, 5, 6A, 6B, 7, and 8. In some embodiments, the example EDRAM fabrication manager 100 provides instructions for the aforementioned methods and/or functionalities to a client machine such that the client machine executes the method, or a portion of the method, based on the instructions provided by the example EDRAM fabrication manager 100. In some embodiments, the example EDRAM fabrication manager 100 comprises software executing on hardware incorporated into a plurality of devices.

The example EDRAM fabrication manager 100 includes a memory 125, storage 130, an interconnect (e.g., BUS) 120, one or more CPUs 105 (also referred to as processors 105 herein), an I/O device interface 110, I/O devices 112, and a network interface 115.

Each CPU 105 retrieves and executes programming instructions stored in the memory 125 or the storage 130. The interconnect 120 is used to move data, such as programming instructions, between the CPUs 105, I/O device interface 110, storage 130, network interface 115, and memory 125. The interconnect 120 can be implemented using one or more busses. The CPUs 105 can be a single CPU, multiple CPUs, or a single CPU having multiple processing cores in various embodiments. In some embodiments, a CPU 105 can be a digital signal processor (DSP). In some embodiments, CPU 105 includes one or more 3D integrated circuits (3DICs) (e.g., 3D wafer-level packaging (3DWLP), 3D interposer based integration, 3D stacked integrated circuits (3D-SICs), monolithic 3D integrated circuits, 3D heterogeneous integration, 3D system in package (3DSiP), and/or package on package (PoP) CPU configurations). Memory 125 is generally included to be representative of a random access memory (e.g., static random access memory (SRAM), dynamic random access memory (DRAM), or Flash). The storage 130 is generally included to be representative of a non-volatile memory, such as a hard disk drive, solid state device (SSD), removable memory cards, optical storage, and/or flash memory devices. Additionally, the storage 130 can include storage area-network (SAN) devices, the cloud, or other devices connected to the example EDRAM fabrication manager 100 via the I/O device interface 110 or to a network 150 via the network interface 115.

In some embodiments, the memory 125 stores instructions 160. However, in various embodiments, the instructions 160 are stored partially in memory 125 and partially in storage 130, or they are stored entirely in memory 125 or entirely in storage 130, or they are accessed over a network 150 via the network interface 115.

Instructions 160 can be processor-executable instructions for performing any portion of, or all, any of the methods described in FIG. 3, and/or cause one or more machines to design, fabricate, and/or utilize components as discussed in FIGS. 2, 4A-4J, 5, 6A, 6B, 7, and 8.

In various embodiments, the I/O devices 112 include an interface capable of presenting information and receiving input. For example, I/O devices 112 can present information to a listener interacting with example EDRAM fabrication manager 100 and receive input from the listener.

The example EDRAM fabrication manager 100 is connected to the network 150 via the network interface 115. Network 150 can comprise a physical, wireless, cellular, or different network.

In some embodiments, the example EDRAM fabrication manager 100 can be a multi-user mainframe computer system, a single-user system, or a server computer or similar device that has little or no direct user interface but receives requests from other computer systems (clients). Further, in some embodiments, the example EDRAM fabrication manager 100 can be implemented as a desktop computer, portable computer, laptop or notebook computer, tablet computer, pocket computer, telephone, smart phone, network switches or routers, or any other appropriate type of electronic device.

It is noted that FIG. 1 is intended to depict the representative major components of an example EDRAM fabrication manager 100. In some embodiments, however, individual components can have greater or lesser complexity than as represented in FIG. 1, components other than or in addition to those shown in FIG. 1 can be present, and the number, type, and configuration of such components can vary.

FIG. 2 is a cross-section view of an example complementary metal-oxide semiconductor (CMOS) device 200 having backside EMRAM, in accordance with some embodiments of the present disclosure. The term, EMRAM, refers to embedded magnetoresistive RAM (MRAM). As stated previously, MRAM is a type of solid state, non-volatile memory that uses tunneling magnetoresistance to store information. The example CMOS device 200 can include a backside 201, bit line (BL) 202, contact 204, hard mask (HM) 206, reference layer (RL) 208, tunneling barrier (TB) 210, free layer (FL) 212, spin Hall effect (SHE) rail 214, BOX 216, contacts 218, contact layer 220, channel layer 222, float layer 224, high-K metal gates 226, word lines 228, bit line layer 230, substrate 232, dielectric encapsulation 234, and dielectric fill 236.

The backside 201 represents a region of the example CMOS device 200 on the other side of the transistors from the substrate 232. The bit line 202 can be a length of electrically conductive material that is useful for writing to a single bit of memory. The contact 204 can be an electrically conductive structure that provides electrical contact between the bit line 202 and the transistors of the example CMOS device 200. The hard mask 206 can be a metallic or dielectric material used to protect the underlying layers from the etching processes used to fabricate the example CMOS device 200.

The reference layer 208 can be a fixed layer where magnetization does not change. Accordingly, when current flows through the reference layer 208, the reference layer 208 produces a spin-polarized current. Accordingly, the reference layer 208 can be composed of cobalt iron boron (CoFeB). The tunneling barrier 210 can be a relatively thin insulation layer that increases the tunneling magneto resistance value. Accordingly, the tunneling barrier 210 can be composed of magnesium oxide (MgO). The free layer 212 can be a layer where magnetization can be changed. For example, when the direction of magnetization of the free layer 212 is the same direction of magnetization as the reference layer 208, the current through junction is relatively high. However, when the direction of magnetization of the free layer 212 is opposite to that of the reference layer 208, the current through junction is relatively low, which is how to store a bit of memory. Accordingly, the free layer 212 can be composed of cobalt iron boron (CoFeB). The SHE rail 214 can provide a transverse pure spin current, and can be composed of tantalum (Ta). The BOX 216 can represent an isolation layer, and can be composed of silicon dioxide (SiO₂). In this way, the reference layer 208, tunneling barrier 210, and free layer 212 can create a magnetic tunnel junction (MTJ). A magnetic tunnel junction (MTJ) can include two layers of magnetic metal (e.g., reference layer 208 and free layer 212), with a layer of insulator (e.g., tunneling barrier 210) that is thin enough to permit electrons to tunnel through if a bias voltage is applied between the reference layer 208 and free layer 212. The MTJ can represent the MRAM cell. Accordingly, the MRAM cell is connected to a source-drain of the transistors by the contacts 218 disposed on the backside of the wafer 200.

The contacts 218 can be similar to the contact 204. The contact layer 220 includes the BOX 216 and the contacts 218. The channel layer 222 can include five transistors of the example CMOS device 200. The float layer 224 can hold the charge of the floating gate transistors of the channel layer 222. The high K metal gates 226 enable the flow of current between source and drain of the example CMOS device 200. The word lines 228 are lengths of electrically conductive material, and can represent an address in memory. Accordingly, a processing device can read a word of memory by reading a specific word line 228. The bit line layer 230 can include bit lines (e.g., BL1 and BL2) for reading individual bits. The substrate 232 can be a layer of dielectric material such as, silicon nitride (SiN). The channel layer 222, float layer 224, and bit line layer 230 can represent the FEOL of the wafer 200. The dielectric encapsulation 234 can be a dielectric material that encapsulates hard mask 206, reference layer 208, tunneling barrier 210, and free layer 212. The dielectric fill 236 can be a dielectric material such as, silicon dioxide (SiO₂).

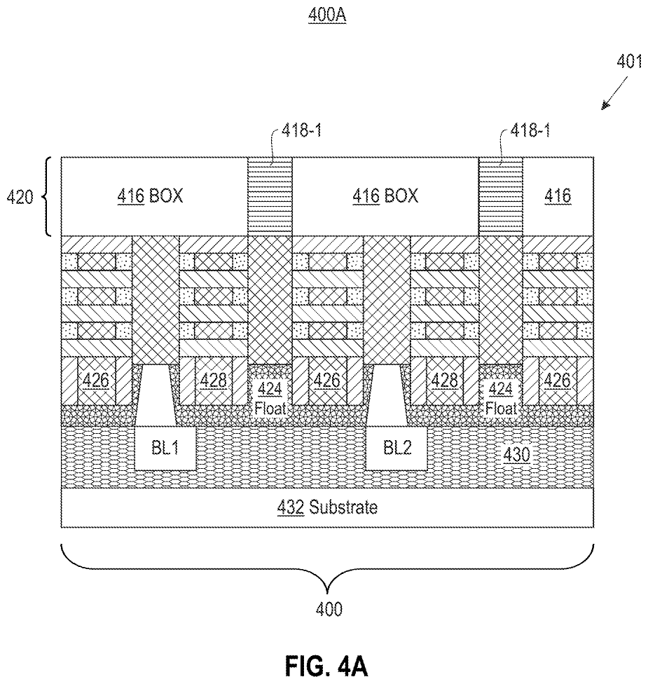

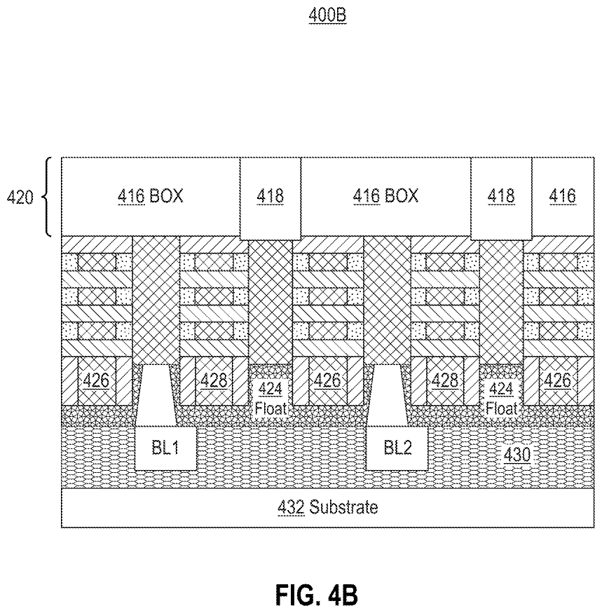

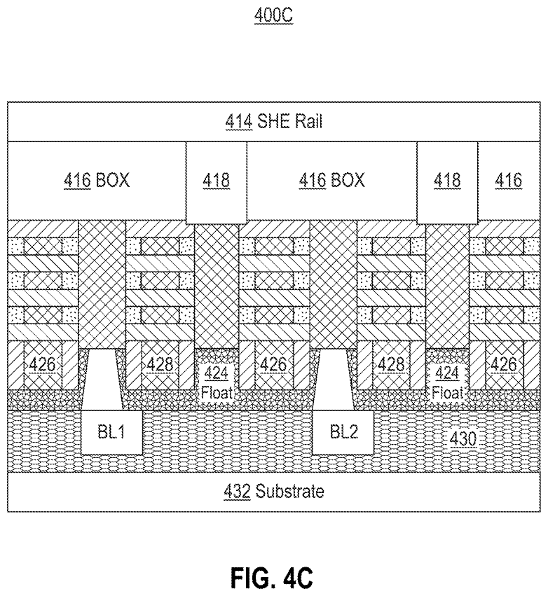

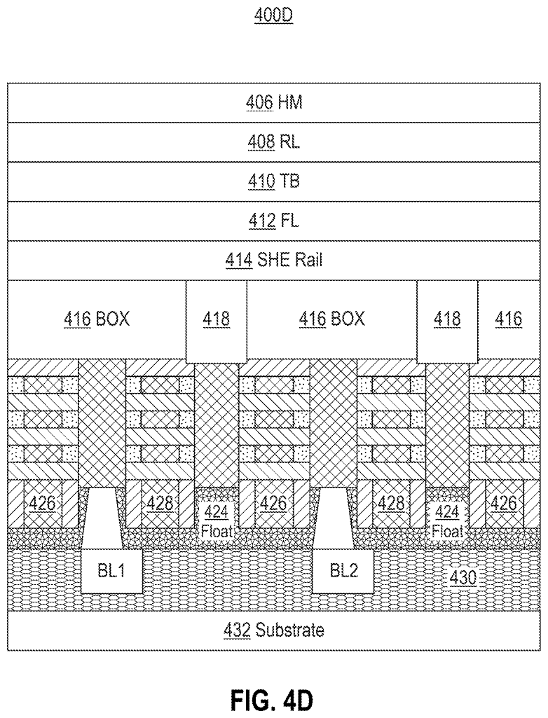

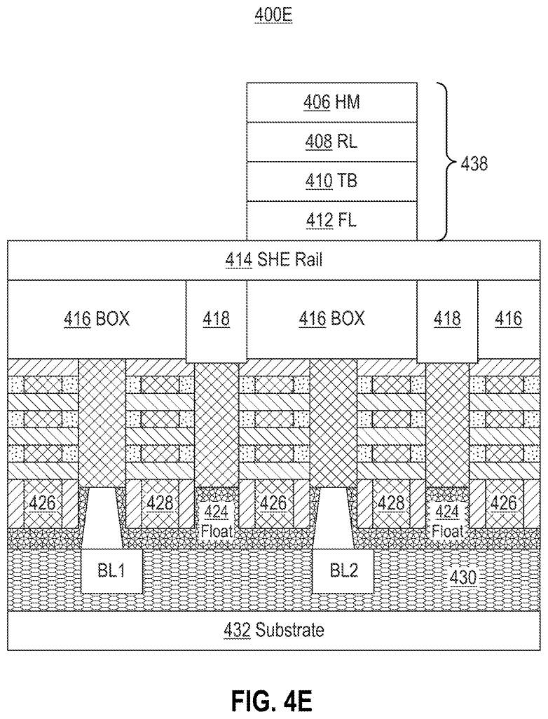

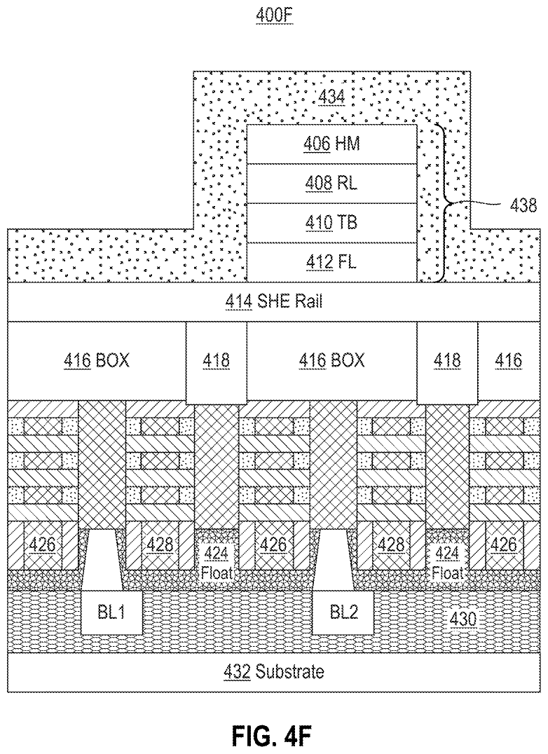

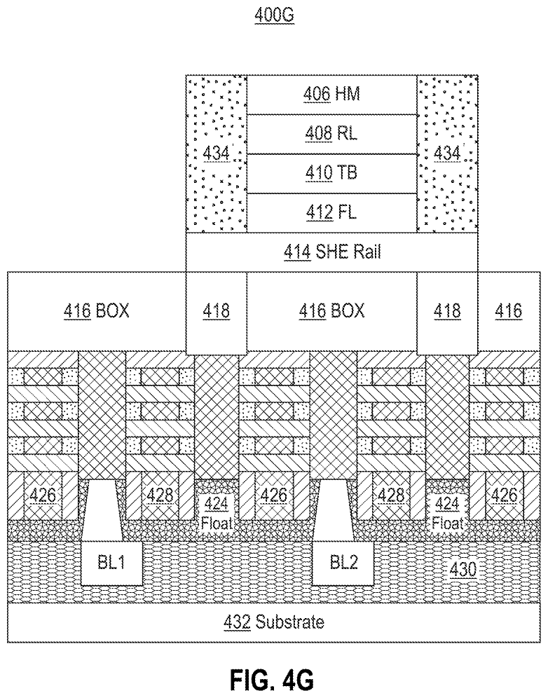

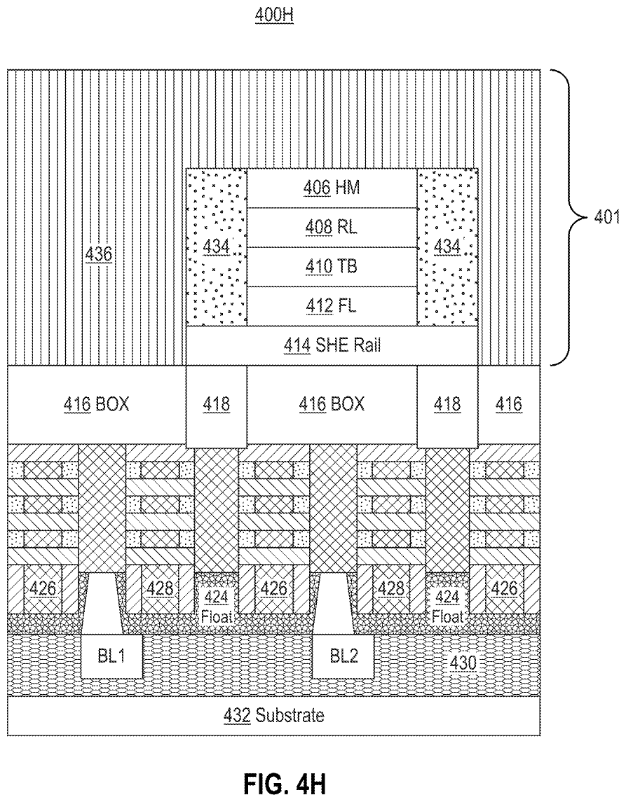

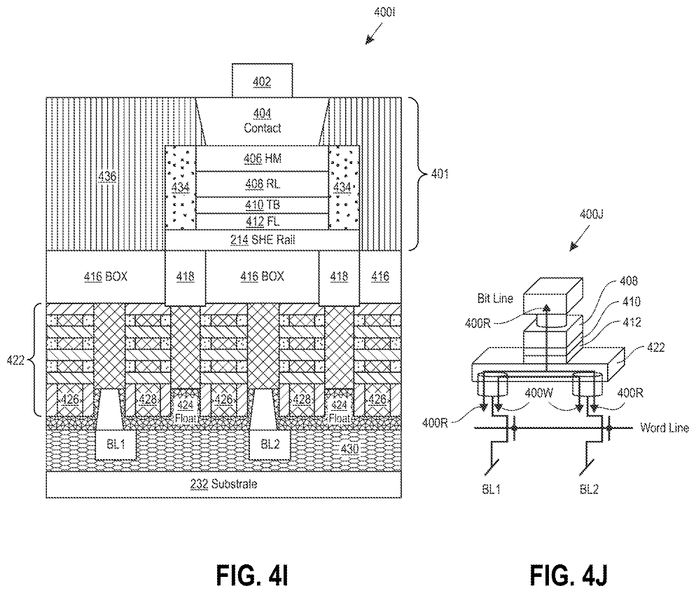

FIG. 3 is a process flow chart of a method 300 for fabricating a CMOS device having backside EMRAM, in accordance with some embodiments of the present disclosure. In some embodiments, an example EMRAM fabrication manager, such as the example EMRAM fabrication manager 100 described with respect to FIG. 1, can perform the method 300. For clarity, the method 300 is described with respect to FIGS. 4A through 4J.

FIG. 4A is a block diagram of an example fabrication state 400A of a wafer 400, in accordance with some embodiments of the present disclosure. The wafer 400 may be a silicon wafer for semiconductor devices. Further, the wafer 400 may include BOX 416, sacrificial plugs 418-1, contacts 418, contact layer 420, float layer 424, high-K metal gates 426, word lines 428, bit line layer 430, and substrate 432. The BOX 416, contacts 418, contact layer 420, float layer 424, high-K metal gates 426, word lines 428, bit line layer 430, and substrate 432 may be similar to the BOX 216, contacts 218, contact layer 220, float layer 224, high-K metal gates 226, word lines 228, bit line layer 230, and substrate 232, described with respect to FIG. 2. The sacrificial plugs 418-1 may be silicon structures the fabrication tool temporarily places within the wafer to create openings for the placement of contacts. At example fabrication state 400A, a backside 401 of the wafer 400 may refer to the top of the contact layer 420. The example fabrication state 400A can represent the wafer 400 after operation 302.

Referring back to FIG. 3, at operation 302, the example EMRAM fabrication manager 100 may direct a fabrication tool to perform post wafer flip and backside polishing. The post wafer flip can involve reversing the position of the wafer 400 within the fabrication tool (not shown). Backside polishing can involve applying a polishing device to the backside 401 of the wafer 400 to remove the silicon substrate material.

FIG. 4B is a block diagram of an example fabrication state 400B of the wafer 400, in accordance with some embodiments of the present disclosure. The wafer 400 may include BOX 416, contacts 418, contact layer 420, float layer 424, high-K metal gates 426, word lines 428, bit line layer 430, and substrate 432. The BOX 416, contact layer 420, float layer 424, high-K metal gates 426, word lines 428, bit line layer 430, and substrate 432 may be similar to the BOX 216, contact layer 220, float layer 224, high-K metal gates 226, word lines 228, bit line layer 230, and substrate 232, described with respect to FIG. 2. The example fabrication state 400B can represent the wafer 400 after operation 304.

Referring back to FIG. 3, at operation 304, the EMRAM fabrication manager 100 can direct the fabrication tool to perform sacrificial plug removal and backside contact formation. Accordingly, the EMRAM fabrication manager 100 can direct the fabrication tool to remove sacrificial plugs 418-1 described with respect to FIG. 4A, and form contacts 418 in their place in the contact layer 420.

FIG. 4C is a block diagram of an example fabrication state 400C of the wafer 400, in accordance with some embodiments of the present disclosure. The wafer 400 may include SHE rail 414, BOX 416, contacts 418, contact layer 420, float layer 424, high-K metal gates 426, word lines 428, bit line layer 430, and substrate 432. The SHE rail 414, BOX 416, contact layer 420, float layer 424, high-K metal gates 426, word lines 428, bit line layer 430, and substrate 432 may be respectively similar to the SHE rail 214, BOX 216, contact layer 220, float layer 224, high-K metal gates 226, word lines 228, bit line layer 230, and substrate 232, described with respect to FIG. 2. The example fabrication state 400C can represent the wafer 400 after operation 306.

Referring back to FIG. 3, at operation 306, the EMRAM fabrication manager 100 can direct the fabrication tool to perform heavy metal SHE rail deposition. Performing heavy metal SHE rail deposition can involve depositing a metal rail on the contact layer 420 to form the SHE rail 414.

FIG. 4D is a block diagram of an example fabrication state 400D of the wafer 400, in accordance with some embodiments of the present disclosure. The wafer 400 may include hard mask 406, reference layer 408, tunneling barrier 410, free layer 412, SHE rail 414, BOX 416, contacts 418, contact layer 420, float layer 424, high-K metal gates 426, word lines 428, bit line layer 430, and substrate 432. The hard mask 406, reference layer 408, tunneling barrier 410, free layer 412, SHE rail 414, BOX 416, contact layer 420, float layer 424, high-K metal gates 426, word lines 428, bit line layer 430, and substrate 432 may be respectively similar to the hard mask 206, reference layer 208, tunneling barrier 210, free layer 212, SHE rail 214, BOX 216, contact layer 220, float layer 224, high-K metal gates 226, word lines 228, bit line layer 230, and substrate 232, described with respect to FIG. 2. The example fabrication state 400D can represent the wafer 400 after operation 308.

Referring back to FIG. 3, at operation 308, the EMRAM fabrication manager 100 can direct the fabrication tool to perform magnetic tunnel junction (MTJ) stack deposition. Performing MTJ stack deposition can involve depositing the free layer 412, tunneling barrier 410, reference layer 408, and hard mask 406 on the SHE rail 414.

FIG. 4E is a block diagram of an example fabrication state 400E of the wafer 400, in accordance with some embodiments of the present disclosure. The wafer 400 may include hard mask 406, reference layer 408, tunneling barrier 410, free layer 412, SHE rail 414, BOX 416, contacts 418, contact layer 420, float layer 424, high-K metal gates 426, word lines 428, bit line layer 430, substrate 432, and ion beam etching (IBE) pillar 438. The hard mask 406, reference layer 408, tunneling barrier 410, free layer 412, SHE rail 414, BOX 416, contact layer 420, float layer 424, high-K metal gates 426, word lines 428, bit line layer 430, and substrate 432 may be respectively similar to the hard mask 206, reference layer 208, tunneling barrier 210, free layer 212, SHE rail 214, BOX 216, contact layer 220, float layer 224, high-K metal gates 226, word lines 228, bit line layer 230, and substrate 232, described with respect to FIG. 2. The IBE pillar 438 can be a patterned formation of the hard mask 406, reference layer 408, tunneling barrier 410, and free layer 412. The example fabrication state 400E can represent the wafer 400 after operation 310.

Referring back to FIG. 3, at operation 310, the EMRAM fabrication manager 100 can direct the fabrication tool to perform MTJ patterning and IBE pillar formation. Performing MTJ patterning and IBE pillar formation can involve directing a beam of charged particles (ions) at the MTJ (e.g., hard mask 406, reference layer 408, tunneling barrier 410, and free layer 412 described with reference to FIG. 4D) with a patterned mask in a high vacuum chamber. In this way, the fabrication tool can form the IBE pillar 438.

FIG. 4F is a block diagram of an example fabrication state 400F of the wafer 400, in accordance with some embodiments of the present disclosure. The wafer 400 may include hard mask 406, reference layer 408, tunneling barrier 410, free layer 412, SHE rail 414, BOX 416, contacts 418, contact layer 420, float layer 424, high-K metal gates 426, word lines 428, bit line layer 430, substrate 432, IBE pillar 438, and dielectric encapsulation 434. The hard mask 406, reference layer 408, tunneling barrier 410, free layer 412, SHE rail 414, BOX 416, contact layer 420, float layer 424, high-K metal gates 426, word lines 428, bit line layer 430, and substrate 432 may be respectively similar to the hard mask 206, reference layer 208, tunneling barrier 210, free layer 212, SHE rail 214, BOX 216, contact layer 220, float layer 224, high-K metal gates 226, word lines 228, bit line layer 230, and substrate 232, described with respect to FIG. 2. The dielectric encapsulation 434 can be a layer of dielectric material. The example fabrication state 400F can represent the wafer 400 after operation 312.

Referring back to FIG. 3, at operation 312, the EMRAM fabrication manager 100 can direct the fabrication tool to perform dielectric encapsulation. Performing dielectric encapsulation can involve depositing a layer of dielectric material on the IBE pillar 438 and the SHE rail 414, leaving the dielectric encapsulation 434.

FIG. 4G is a block diagram of an example fabrication state 400G of the wafer 400, in accordance with some embodiments of the present disclosure. The wafer 400 may include hard mask 406, reference layer 408, tunneling barrier 410, free layer 412, SHE rail 414, BOX 416, contacts 418, contact layer 420, float layer 424, high-K metal gates 426, word lines 428, bit line layer 430, substrate 432, and dielectric encapsulation 434. The hard mask 406, reference layer 408, tunneling barrier 410, free layer 412, SHE rail 414, BOX 416, contact layer 420, float layer 424, high-K metal gates 426, word lines 428, bit line layer 430, substrate 432, and dielectric encapsulation 434 may be respectively similar to the hard mask 206, reference layer 208, tunneling barrier 210, free layer 212, SHE rail 214, BOX 216, contact layer 220, float layer 224, high-K metal gates 226, word lines 228, bit line layer 230, substrate 232, and dielectric encapsulation 234 described with respect to FIG. 2. The example fabrication state 400G can represent the wafer 400 after operation 314.

Referring back to FIG. 3, at operation 314, the EMRAM fabrication manager 100 can direct the fabrication tool to perform self-aligned encapsulation dielectric reactive ion etching (RIE) and SHE rail formation. Performing self-aligned encapsulation dielectric reactive ion etching (RIE) and SHE rail formation can involve plasma etching where ions are accelerated toward the dielectric encapsulation 434 and SHE rail 414 to remove deposited material as shown.

FIG. 4H is a block diagram of an example fabrication state 400H of the wafer 400, in accordance with some embodiments of the present disclosure. The wafer 400 may include backside 401, hard mask 406, reference layer 408, tunneling barrier 410, free layer 412, SHE rail 414, BOX 416, contacts 418, contact layer 420, float layer 424, high-K metal gates 426, word lines 428, bit line layer 430, substrate 432, dielectric encapsulation 434, and dielectric fill 436. The hard mask 406, reference layer 408, tunneling barrier 410, free layer 412, SHE rail 414, BOX 416, contact layer 420, float layer 424, high-K metal gates 426, word lines 428, bit line layer 430, substrate 432, dielectric encapsulation 434, and dielectric fill 436 may be respectively similar to the hard mask 206, reference layer 208, tunneling barrier 210, free layer 212, SHE rail 214, BOX 216, contact layer 220, float layer 224, high-K metal gates 226, word lines 228, bit line layer 230, substrate 232, dielectric encapsulation 234, and dielectric fill 236 described with respect to FIG. 2. The example fabrication state 400H can represent the wafer 400 after operation 316.

Referring back to FIG. 3, at operation 316, the EMRAM fabrication manager 100 can direct the fabrication tool to perform interlayer dielectric (ILD) fill and chemical-mechanical polishing (CMP). Performing ILD fill can involve depositing a layer of dielectric material (e.g., the dielectric fill 436) on the backside 401 of the wafer 400. Additionally, CMP can involve smoothing the surfaces of the dielectric encapsulation 434 and dielectric fill 436 with chemical application and mechanical force.

FIG. 4I is a block diagram of an example fabrication state 400I of the wafer 400, in accordance with some embodiments of the present disclosure. The wafer 400 may include backside 401, bit line 402, contact 404, hard mask 406, reference layer 408, tunneling barrier 410, free layer 412, SHE rail 414, BOX 416, contacts 418, contact layer 420, float layer 424, high-K metal gates 426, word lines 428, bit line layer 430, substrate 432, dielectric encapsulation 434, and dielectric fill 436. The bit line 402, contact 404, hard mask 406, reference layer 408, tunneling barrier 410, free layer 412, SHE rail 414, BOX 416, contact layer 420, float layer 424, high-K metal gates 426, word lines 428, bit line layer 430, substrate 432, dielectric encapsulation 434, and dielectric fill 436 may be respectively similar to the bit line 202, contact 204, hard mask 206, reference layer 208, tunneling barrier 210, free layer 212, SHE rail 214, BOX 216, contact layer 220, float layer 224, high-K metal gates 226, word lines 228, bit line layer 230, substrate 232, dielectric encapsulation 234, and dielectric fill 236, described with respect to FIG. 2. The example fabrication state 400I can represent the wafer 400 after operation 318.

Referring back to FIG. 3, at operation 318, the EMRAM fabrication manager 100 can direct the fabrication tool to perform MTJ top contact landing. Performing MTJ top contact landing can involve forming contact 404 on the hard mask 406, and bit line 402 on the contact 404. Accordingly, the wafer 400 can be similar to the example CMOS device 200 having backside EMRAM, described with respect to FIG. 2.

FIG. 4J is a side perspective view of a wafer 400J having a CMOS device with backside EMRAM, in accordance with some embodiments of the present disclosure. The wafer 400J may be similar to the wafer 400 in example fabrication state 400I, and example CMOS device 200 having backside EMRAM. Further, the wafer 400J represents the path of electrons during read and write operations to the wafer 400J. Accordingly, the wafer 400J includes bit line 402, contact 404, reference layer 408, tunneling barrier 410, free layer 412, channel layer 422, word line 428, bit line 1 (BL1), and bit line 2 (BL2). The flow of electrons during a read operation is represented in lines 400R. Additionally, the flow of electrons during a write operation is represented in lines 400W.

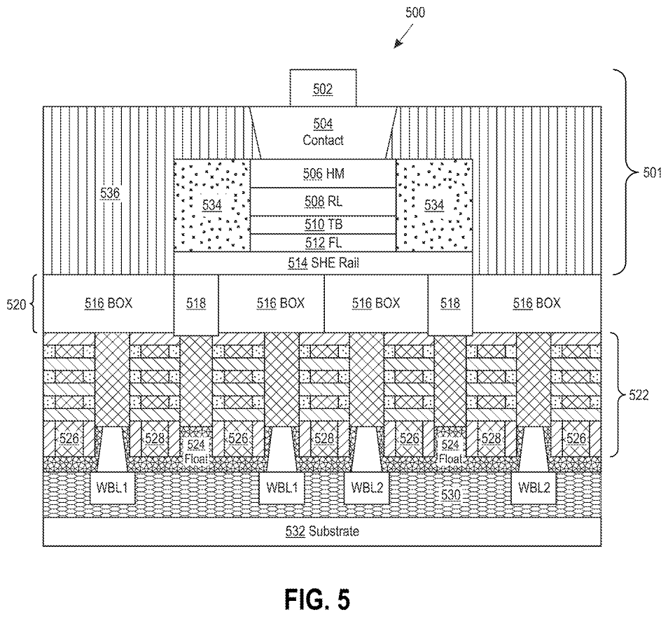

Additionally, the method 300 can also be performed for additional contacts and/or MTJ stacks in embodiments having more than shown in wafer 400. Such embodiments are described with respect to FIGS. 5, 6A, 6B, 7, and 8.

FIG. 5 is a cross-section view of an example CMOS device 500 having backside EMRAM, in accordance with some embodiments of the present disclosure. The example CMOS device 500 can include a backside 501, bit line 502, contact 504, hard mask 506, reference layer 508, tunneling barrier 510, free layer 512, SHE rail 514, BOX 516, contacts 518, contact layer 520, channel layer 522, float layer 524, high-K metal gates 526, word lines 528, bit line layer 530, substrate 532, dielectric encapsulation 534, and dielectric fill 536. The bit line 502, contact 504, hard mask 506, reference layer 508, tunneling barrier 510, free layer 512, SHE rail 514, BOX 516, contact layer 520, channel layer 522, float layer 524, high-K metal gates 526, word lines 528, bit line layer 530, substrate 532, dielectric encapsulation 534, and dielectric fill 536 may be respectively similar to the bit line 202, contact 204, hard mask 206, reference layer 208, tunneling barrier 210, free layer 212, SHE rail 214, BOX 216, contact layer 220, channel layer 222, float layer 224, high-K metal gates 226, word lines 228, bit line layer 230, substrate 232, dielectric encapsulation 234, and dielectric fill 236 described with respect to FIG. 2.

In contrast to the example CMOS device 200 having backside EMRAM, the contact layer 520 can include four BOX 516, the channel layer 522 can include seven transistors, and the float layer 524 can include four contacts 518. Additionally, the bit line layer 530 can include four bit lines each associated with one of the contacts 518 in the float layer 524. In this way, the CMOS device 500 can include one more transistor for each contact 518 than in the CMOS device 200. Accordingly, the extra transistor can improve the flow of current to the SHE rail 514, and hence, the ability to flip the MTJ (e.g., free layer 512, tunneling barrier 510, and reference layer 508). In this way, the wafer 500 makes it possible to drive more current to the SHE rail 514 than to the SHE rail 414, described with respect to FIG. 4. This ability is also referred to as high drive current herein.

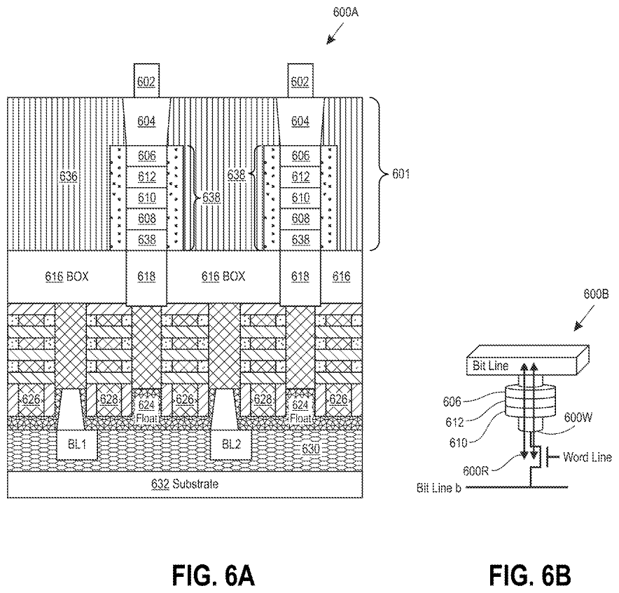

FIG. 6A is a cross-section view of an example CMOS device 600A having backside EMRAM, in accordance with some embodiments of the present disclosure. The example CMOS device 600 can include a backside 601, bit line 602, contact 604, hard mask 606, reference layer 608, tunneling barrier 610, free layer 612, SHE rail 614, BOX 616, contacts 618, contact layer 620, channel layer 622, float layer 624, high-K metal gates 626, word lines 628, bit line layer 630, substrate 632, dielectric encapsulation 634, and dielectric fill 636. The bit line 602, contact 604, hard mask 606, reference layer 608, tunneling barrier 610, free layer 612, SHE rail 614, BOX 616, contact layer 620, channel layer 622, float layer 624, high-K metal gates 626, word lines 628, bit line layer 630, substrate 632, dielectric encapsulation 634, and dielectric fill 636 may be respectively similar to the bit line 202, contact 204, hard mask 206, reference layer 208, tunneling barrier 210, free layer 212, SHE rail 214, BOX 216, contact layer 220, channel layer 222, float layer 224, high-K metal gates 226, word lines 228, bit line layer 230, substrate 232, dielectric encapsulation 234, and dielectric fill 236 described with respect to FIG. 2.

In contrast to the example CMOS device 200 having backside EMRAM, the backside 601 can include two IBE pillars 638. Accordingly, each IBE pillar 638 can be topped with one contact 604 and bit line 602. In some embodiments of the present disclosure, the example CMOS device 600A can represent a spin-transfer torque MRAM or a voltage-controlled MRAM (VC-MRAM). The VC-MRAM is type of spin-orbit torque MRAM with a three-terminal design.

FIG. 6B is a side perspective view 600B of the CMOS device 600A having backside EMRAM. Accordingly, the side perspective view 600B shows the bit line 602, contact 604, hard mask 606, free layer 612, and tunneling barrier 610. Further, when performing read and write operations, the flow of electrons may follow lines 600R and 600W, respectively.

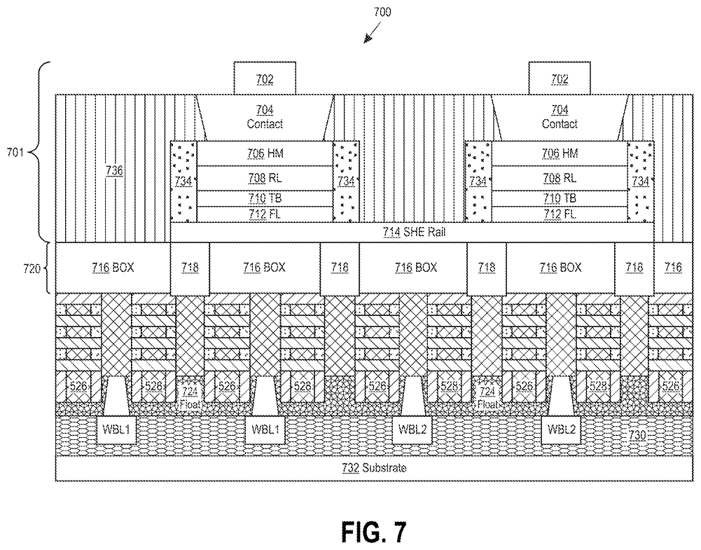

FIG. 7 is a cross-section view of an example CMOS device 700 having backside EMRAM, in accordance with some embodiments of the present disclosure. The example CMOS device 700 can include a backside 701, bit line 702, contact 704, hard mask 706, reference layer 708, tunneling barrier 710, free layer 712, SHE rail 714, BOX 716, contacts 718, contact layer 720, channel layer 722, float layer 724, high-K metal gates 726, word lines 728, bit line layer 730, substrate 732, dielectric encapsulation 734, and dielectric fill 736. The bit line 702, contact 704, hard mask 706, reference layer 708, tunneling barrier 710, free layer 712, SHE rail 714, BOX 716, contacts 718, contact layer 720, channel layer 722, float layer 724, high-K metal gates 726, word lines 728, bit line layer 730, substrate 732, dielectric encapsulation 734, and dielectric fill 736 may be respectively similar to the bit line 202, contact 204, hard mask 206, reference layer 208, tunneling barrier 210, free layer 212, SHE rail 214, BOX 216, contacts 218, contact layer 220, channel layer 222, float layer 224, high-K metal gates 226, word lines 228, bit line layer 230, substrate 232, dielectric encapsulation 234, and dielectric fill 236 described with respect to FIG. 2.

In contrast to the example CMOS device 200 having backside EMRAM, the backside 701 can include two IBE pillars 738. Accordingly, each IBE pillar 738 can be topped with one contact 704 and bit line 702. Additionally, the contact layer 720 includes five BOX 716 and four contacts 718. Accordingly, the bit line layer 730 includes four bit lines.

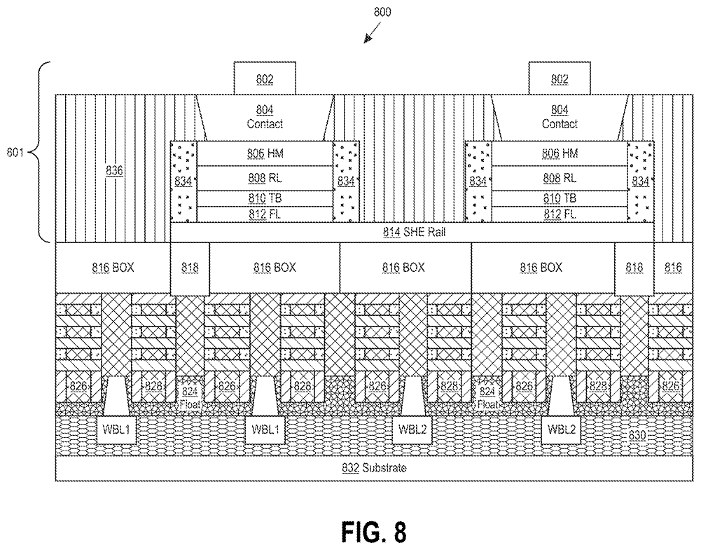

FIG. 8 is a cross-section view of an example CMOS device 800 having backside EMRAM, in accordance with some embodiments of the present disclosure. The example CMOS device 800 can include a backside 801, bit line 802, contact 804, hard mask 806, reference layer 808, tunneling barrier 810, free layer 812, SHE rail 814, BOX 816, contacts 818, contact layer 820, channel layer 822, float layer 824, high-K metal gates 826, word lines 828, bit line layer 830, substrate 832, dielectric encapsulation 834, and dielectric fill 836. The bit line 802, contact 804, hard mask 806, reference layer 808, tunneling barrier 810, free layer 812, SHE rail 814, BOX 816, contacts 818, contact layer 820, channel layer 822, float layer 824, high-K metal gates 826, word lines 828, bit line layer 830, substrate 832, dielectric encapsulation 834, and dielectric fill 836 may be respectively similar to the bit line 202, contact 204, hard mask 206, reference layer 208, tunneling barrier 210, free layer 212, SHE rail 214, BOX 216, contacts 218, contact layer 220, channel layer 222, float layer 224, high-K metal gates 226, word lines 228, bit line layer 230, substrate 232, dielectric encapsulation 234, and dielectric fill 236 described with respect to FIG. 2.

In contrast to the example CMOS device 200 having backside EMRAM, the backside 801 can include two IBE pillars 838. Accordingly, each IBE pillar 838 can be topped with one contact 804 and bit line 802. Additionally, the contact layer 820 includes five BOX 816 and two contacts 818. Further, the float layer 824 includes four contacts 818, and the bit line layer 830 includes four bit lines, accordingly.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

A non-limiting list of examples are provided below, consistent with embodiments of the present disclosure. Example 1 is a system. The system includes a wafer; a plurality of transistors disposed on a front end of line (FEOL) of the wafer; and a magnetoresistive random access memory (MRAM) cell disposed on the wafer, wherein: the MRAM cell is disposed on a backside of the wafer; the MRAM cell is connected to a source-drain of the transistors by a contact disposed on the backside of the wafer; and the plurality of transistors are in direct electrical contact with the MRAM cell by at least one contact.

Example 2 includes the system of example 1, including or excluding optional features. In this example, the MRAM cell comprises a magnetic tunnel junction comprising: a reference layer; a tunnel barrier; and a free layer.

Example 3 includes the system of any one of examples 1 to 2, including or excluding optional features. In this example, the plurality of transistors are in direct electrical contact with the MRAM cell by a plurality of contacts for high drive current.

Example 4 includes the system of any one of examples 1 to 3, including or excluding optional features. In this example, the plurality of transistors are in direct electrical contact with a plurality of word bit lines by a plurality of contacts for high drive current.

Example 5 includes the system of any one of examples 1 to 4, including or excluding optional features. In this example, the system comprises an additional MRAM cell comprising an additional magnetic tunnel junction. Optionally, the plurality of transistors are in direct electrical contact with the additional MRAM cell by at least one contact. Optionally, the MRAM cell comprises a spin transfer torque MRAM. Optionally, the MRAM cell comprises a voltage controlled MRAM.

Example 6 is a system. The system includes a wafer; a plurality of transistors disposed on a front end of line (FEOL) of the wafer; a first magnetoresistive random access memory (MRAM) cell disposed on a backside of the wafer, wherein the first MRAM cell is connected to a source-drain of the transistors by a first contact disposed on the backside of the wafer, and wherein the plurality of transistors are in direct electrical contact with the first MRAM cell; and a second MRAM cell disposed on the backside of the wafer, wherein the second MRAM cell is connected to the source-drain of the transistors by a second contact disposed on the backside of the wafer, and wherein the plurality of transistors are in direct electrical contact with the second MRAM cell.

Example 7 includes the system of example 6, including or excluding optional features. In this example, the first MRAM cell and the second MRAM cell comprise a magnetic tunnel junction comprising: a reference layer; a tunnel barrier; and a free layer.

Example 8 includes the system of any one of examples 6 to 7, including or excluding optional features. In this example, the plurality of transistors are in direct electrical contact with the first MRAM cell and the second MRAM cell by a plurality of contacts for high drive current.

Example 9 includes the system of any one of examples 6 to 8, including or excluding optional features. In this example, the plurality of transistors are in direct electrical contact with a plurality of word bit lines by a plurality of contacts for high drive current.

Example 10 includes the system of any one of examples 6 to 9, including or excluding optional features. In this example, the first MRAM cell and second MRAM cell comprise a spin transfer torque MRAM.

Example 11 includes the system of any one of examples 6 to 10, including or excluding optional features. In this example, the first MRAM cell and second MRAM cell comprise a voltage controlled MRAM.

Example 12 is a system. The system includes a wafer; a plurality of transistors disposed on a front end of line (FEOL) of the wafer; a first magnetoresistive random access memory (MRAM) cell disposed on a backside of the wafer, wherein the first MRAM cell is connected to a source-drain of the transistors by a first contact disposed on the backside of the wafer, and wherein the plurality of transistors are in direct electrical contact with the first MRAM cell; and a second MRAM cell disposed on the backside of the wafer, wherein the second MRAM cell is connected to the source-drain of the transistors by a second contact disposed on the backside of the wafer, and wherein the plurality of transistors are in direct electrical contact with the second MRAM cell, and wherein the plurality of transistors are in direct electrical contact with the first MRAM cell and the second MRAM cell by a plurality of contacts for high drive current. Optionally, the first MRAM cell and the second MRAM cell comprise a magnetic tunnel junction comprising: a reference layer; a tunnel barrier; and a free layer.

Example 13 includes the system of example 12, including or excluding optional features. In this example, the plurality of transistors are in direct electrical contact with a plurality of word bit lines by a plurality of contacts for high drive current.

Example 14 includes the system of any one of examples 12 to 13, including or excluding optional features. In this example, the first MRAM cell and second MRAM cell comprise a spin transfer torque MRAM.

Example 15 includes the system of any one of examples 12 to 14, including or excluding optional features. In this example, the first MRAM cell and second MRAM cell comprise a voltage controlled MRAM.

Example 16 is a computer program product comprising program instructions stored on a computer readable storage medium. The computer-readable medium includes instructions that direct the processor to performing a post wafer flip of a wafer comprising a plurality of transistors disposed on a front end of line (FEOL) of the wafer; performing backside polishing of the wafer; removing a plurality of sacrificial plugs from a backside of the wafer; forming a plurality of contacts in place of the sacrificial plugs; generating a spin Hall effect (SHE) rail by performing heavy metal SHE rail deposition on the backside of the wafer; generating a magnetic tunnel junction (MTJ) stack by performing MTJ stack deposition on the SHE rail; performing MTJ patterning on the MTJ stack; generating an IBE pillar by performing IBE pillar formation on the patterned MTJ stack; performing dielectric encapsulation on the SHE rail and the IBE pillar; performing self-aligned encapsulation dielectric reactive ion etching (RIE) and SHE rail formation; performing interlayer dielectric (ILD) fill and chemical-mechanical polishing (CMP) on the IBE pillar and SHE rail; and performing MTJ top contact landing on the IBE pillar.

Example 17 includes the computer-readable medium of example 16, including or excluding optional features. In this example, the computer-readable medium includes generating an additional MTJ stack by performing an additional MTJ stack deposition on the SHE rail; performing MTJ patterning on the additional MTJ stack; generating an additional IBE pillar by performing IBE pillar formation on the patterned additional MTJ stack; performing dielectric encapsulation on the SHE rail and the additional IBE pillar; performing ILD fill and CMP on the additional IBE pillar; and performing MTJ top contact landing on the additional IBE pillar.

Example 18 includes the computer-readable medium of any one of examples 16 to 17, including or excluding optional features. In this example, forming the plurality of contacts in place of the sacrificial plugs comprises forming a plurality of contacts for one of the transistors, such that the formed plurality of contacts are configured to conduct high drive current.

Example 19 is a method for fabricating a complementary metal oxide semiconductor (CMOS) with backside MRAM. The method includes instructions that direct the processor to performing a post wafer flip of a wafer comprising a plurality of transistors disposed on a front end of line (FEOL) of the wafer; performing backside polishing of the wafer; removing a plurality of sacrificial plugs from a backside of the wafer; forming a plurality of contacts in place of the sacrificial plugs; generating a spin Hall effect (SHE) rail by performing heavy metal SHE rail deposition on the backside of the wafer; generating a magnetic tunnel junction (MTJ) stack by performing MTJ stack deposition on the SHE rail; performing MTJ patterning on the MTJ stack; generating an IBE pillar by performing IBE pillar formation on the patterned MTJ stack; performing dielectric encapsulation on the SHE rail and the IBE pillar; performing self-aligned encapsulation dielectric reactive ion etching (RIE) and SHE rail formation; performing interlayer dielectric (ILD) fill and chemical-mechanical polishing (CMP) on the IBE pillar and SHE rail; and performing MTJ top contact landing on the IBE pillar.

Example 20 includes the method of example 19, including or excluding optional features. In this example, the method includes generating an additional MTJ stack by performing an additional MTJ stack deposition on the SHE rail; performing MTJ patterning on the additional MTJ stack; generating an additional IBE pillar by performing IBE pillar formation on the patterned additional MTJ stack; performing dielectric encapsulation on the SHE rail and the additional IBE pillar; performing ILD fill and CMP on the additional IBE pillar; and performing MTJ top contact landing on the additional IBE pillar.

Example 21 includes the method of any one of examples 19 to 20, including or excluding optional features. In this example, forming the plurality of contacts in place of the sacrificial plugs comprises forming a plurality of contacts for one of the transistors, such that the formed plurality of contacts are configured to conduct high drive current.

What is claimed is:

1. A system comprising:
a wafer;
a plurality of transistors disposed on a front end of line (FEOL) of the wafer; and
a magnetoresistive random access memory (MRAM) cell disposed on the wafer, wherein:
the MRAM cell is disposed on a backside of the wafer;
the MRAM cell is connected to a source-drain of the transistors by a contact disposed on the backside of the wafer; and
the plurality of transistors are in direct electrical contact with the MRAM cell.

2. The system of claim 1, wherein the MRAM cell comprises a magnetic tunnel junction comprising:
a reference layer;
a tunnel barrier; and
a free layer.

3. The system of claim 1, wherein the plurality of transistors are in direct electrical contact with the MRAM cell by a plurality of contacts for high drive current.

4. The system of claim 1, wherein the plurality of transistors are in direct electrical contact with a plurality of word bit lines by a plurality of contacts for high drive current.

5. The system of claim 1, wherein the system comprises an additional MRAM cell comprising an additional magnetic tunnel junction.

6. The system of claim 5, wherein the plurality of transistors are in direct electrical contact with the additional MRAM cell by at least one contact.

7. The system of claim 5, wherein the MRAM cell comprises a spin transfer torque MRAM.

8. The system of claim 5, wherein the MRAM cell comprises a voltage controlled MRAM.

9. A system comprising:
a wafer;
a plurality of transistors disposed on a front end of line (FEOL) of the wafer;
a first magnetoresistive random access memory (MRAM) cell disposed on a backside of the wafer, wherein the first MRAM cell is connected to a source-drain of the transistors by a first contact disposed on the backside of the wafer, and wherein the plurality of transistors are in direct electrical contact with the first MRAM cell; and
a second MRAM cell disposed on the backside of the wafer, wherein the second MRAM cell is connected to the source-drain of the transistors by a second contact disposed on the backside of the wafer, and wherein the plurality of transistors are in direct electrical contact with the second MRAM cell.

10. The system of claim 9, wherein the first MRAM cell and the second MRAM cell comprise a magnetic tunnel junction comprising:
a reference layer;
a tunnel barrier; and
a free layer.

11. The system of claim 9, wherein the plurality of transistors are in direct electrical contact with the first MRAM cell and the second MRAM cell by a plurality of contacts for high drive current.

12. The system of claim 9, wherein the plurality of transistors are in direct electrical contact with a plurality of word bit lines by a plurality of contacts for high drive current.

13. The system of claim 9, wherein the first MRAM cell and the second MRAM cell comprise a spin transfer torque MRAM.

14. The system of claim 9, wherein the first MRAM cell and the second MRAM cell comprise a voltage controlled MRAM.

15. A system comprising:
a wafer;
a plurality of transistors disposed on a front end of line (FEOL) of the wafer;
a first magnetoresistive random access memory (MRAM) cell disposed on a backside of the wafer, wherein the first MRAM cell is connected to a source-drain of the transistors by a first contact disposed on the backside of the wafer, and wherein the plurality of transistors are in direct electrical contact with the first MRAM cell; and
a second MRAM cell disposed on the backside of the wafer, wherein the second MRAM cell is connected to the source-drain of the transistors by a second contact disposed on the backside of the wafer, and wherein the plurality of transistors are in direct electrical contact with the second MRAM cell, and wherein the plurality of transistors are in direct electrical contact with the first MRAM cell and the second MRAM cell by a plurality of contacts for high drive current.

16. The system of claim 9, wherein the first MRAM cell and the second MRAM cell comprise a magnetic tunnel junction (MTJ) comprising:
a reference layer;
a tunnel barrier; and
a free layer.

17. The system of claim 16, wherein an ion beam etched (IBE) pillar comprises the MTJ.

18. The system of claim 15, wherein the first MRAM cell and the second MRAM cell comprise a spin transfer torque MRAM.

19. The system of claim 15, wherein the first MRAM cell and the second MRAM cell comprise a voltage controlled MRAM.

20. A computer program product comprising program instructions stored on a computer readable storage medium, the program instructions executable by a processor to cause the processor to perform a method comprising:
performing a post wafer flip of a wafer comprising a plurality of transistors disposed on a front end of line (FEOL) of the wafer;
performing backside polishing of the wafer;
removing a plurality of sacrificial plugs from a backside of the wafer;
forming a plurality of contacts in place of the sacrificial plugs;
generating a spin Hall effect (SHE) rail by performing heavy metal SHE rail deposition on the backside of the wafer;
generating a magnetic tunnel junction (MTJ) stack by performing MTJ stack deposition on the SHE rail;
performing MTJ patterning on the MTJ stack;
generating an IBE pillar by performing IBE pillar formation on the patterned MTJ stack;
performing dielectric encapsulation on the SHE rail and the IBE pillar;
performing self-aligned encapsulation dielectric reactive ion etching (RIE) and SHE rail formation;
performing interlayer dielectric (ILD) fill and chemical-mechanical polishing (CMP) on the IBE pillar and the SHE rail; and
performing MTJ top contact landing on the IBE pillar.

21. The computer program product of claim 20, the method further comprising:
generating an additional MTJ stack by performing an additional MTJ stack deposition on the SHE rail;
performing MTJ patterning on the additional MTJ stack;
generating an additional IBE pillar by performing IBE pillar formation on the patterned additional MTJ stack;
performing dielectric encapsulation on the SHE rail and the additional IBE pillar;
performing ILD fill and CMP on the additional IBE pillar; and
performing MTJ top contact landing on the additional IBE pillar.

22. The computer program product of claim 20, wherein forming the plurality of contacts in place of the sacrificial plugs comprises forming a plurality of contacts for one of the transistors, such that the formed plurality of contacts are configured to conduct high drive current.

23. A method for fabricating a complementary metal oxide semiconductor (CMOS) with backside MRAM, comprising:
performing a post wafer flip of a wafer comprising a plurality of transistors disposed on a front end of line (FEOL) of the wafer;
performing backside polishing of the wafer;
removing a plurality of sacrificial plugs from a backside of the wafer;
forming a plurality of contacts in place of the sacrificial plugs;
generating a spin Hall effect (SHE) rail by performing heavy metal SHE rail deposition on the backside of the wafer;
generating a magnetic tunnel junction (MTJ) stack by performing MTJ stack deposition on the SHE rail;
performing MTJ patterning on the MTJ stack;
generating an IBE pillar by performing IBE pillar formation on the patterned MTJ stack;
performing dielectric encapsulation on the SHE rail and the IBE pillar;
performing self-aligned encapsulation dielectric reactive ion etching (RIE) and SHE rail formation;
performing interlayer dielectric (ILD) fill and chemical-mechanical polishing (CMP) on the IBE pillar and the SHE rail; and
performing MTJ top contact landing on the IBE pillar.

24. The method of claim 23, further comprising:
generating an additional MTJ stack by performing an additional MTJ stack deposition on the SHE rail;
performing MTJ patterning on the additional MTJ stack;
generating an additional IBE pillar by performing IBE pillar formation on the patterned additional MTJ stack;
performing dielectric encapsulation on the SHE rail and the additional IBE pillar;
performing ILD fill and CMP on the additional IBE pillar; and
performing MTJ top contact landing on the additional IBE pillar.

25. The method of claim 23, wherein forming the plurality of contacts in place of the sacrificial plugs comprises forming a plurality of contacts for one of the transistors, such that the formed plurality of contacts are configured to conduct high drive current.
